(19) United States
(12) Patent Application Publication
(10) Pub. No.: US 2022/0146104 A1
(43) Pub. Date: May 12, 2022

(54) TEMPERATURE CONTROLLER FOR A GAS OVEN AND THE GAS OVEN USING THE TEMPERATURE CONTROLLER

(71) Applicant: JIANGSU JIUHUI TECHNOLOGY CO., LTD., Taizhou (CN)

(72) Inventors: Lanyu YANG, Taizhou (CN); Tao CHEN, Taizhou (CN); Xifeng YANG, Taizhou (CN); Jiuhui BIAN, Taizhou (CN); Wei GU, Taizhou (CN); Wenbin MA, Taizhou (CN); Ming HE, Taizhou (CN); Zhengbing ZHU, Taizhou (CN); Xuedan LIU, Taizhou (CN)

(73) Assignee: JIANGSU JIUHUI TECHNOLOGY CO., LTD., Taizhou (CN)

(21) Appl. No.: 17/161,701

(22) Filed: Jan. 29, 2021

Related U.S. Application Data
(63) Continuation of application No. PCT/CN2020/130272, filed on Nov. 20, 2020.

(30) Foreign Application Priority Data
Nov. 9, 2020 (CN) 202011242441.4

(51) Int. Cl. F24C 3/12; F27D 19/00; F27D 21/00; F27D 21/02; F27D 21/04

(52) U.S. Cl. CPC F24C 3/124; F27D 19/00; F27D 21/0014; F27D 2019/004; F27D 21/04; F27D 2019/0018; F27D 21/02

(57) ABSTRACT

A temperature controller for a gas oven includes a control module, a temperature measurement module, a prompt module, and a gas regulating module. The control module is connected to the temperature measurement module, the prompt module, and the gas regulating module, respectively, to transmit a signal. The temperature measurement module is arranged in the oven to measure a temperature in the oven and return the temperature to the control module. The prompt module is configured to receive an excessive temperature or a normal temperature of the control module, and provide a prompt. The gas regulating module is configured to receive a temperature and a control quantity returned by the control module, and control an air intake quantity, to adjust the temperature or turn on or turn off the oven. A micro-switch is provided and an on signal and an off signal of the micro-switch are transmitted to the control module.

### CROSS REFERENCE TO THE RELATED APPLICATIONS

This application is a continuation application of International Application No. PCT/CN2020/130272, filed on Nov. 20, 2020, which is based upon and claims priority to Chinese Patent Application No. 202011242441.4, filed on Nov. 9, 2020, the entire contents of which are incorporated herein by reference.

### TECHNICAL FIELD

The present invention relates to the technical field of gas ovens, and in particular, to a temperature controller for a gas oven and the gas oven using the temperature controller.

### BACKGROUND

An oven is a device that forms hot air to bake and cook food, and is generally a closed or semi-closed structure. Ovens are also called oasts, toasters, and roasters, and those heated with hot air in an open form are called barbecues. In a general sense, an oven also refers to a device that performs high-temperature treatment with hot gas. Traditional ovens use wood and coal for burning and heating. Modern ovens are multi-functional and use electric heating or natural gas. Ovens are divided into a single-layer type, a double-layer type and a three-layer type. Each layer can be controlled independently and can be used at the same time.

Currently, most gas ovens do not provide precise temperature control, and it is thus difficult to adjust to the appropriate temperature in use, resulting in much inconvenience during use. Moreover, the flame adjustment of gas ovens typically requires manual adjustment by the user, which is time-consuming, laborious and extremely inconvenient. Additionally, gas ovens generally lack heat dissipation of internal electronic components, which increases the risk of damaging the internal electronic components, thereby seriously affecting use. Furthermore, gas ovens typically rely on external power sources for electrical connection and thus have limitations on where they can be placed, resulting in limited utility.

### SUMMARY

### (1) Technical Problems to be Solved

In view of the shortcomings in the prior art, the present invention provides a temperature-controlled gas oven, which solves the problems and limitations of accurate temperature control, requirement for manual adjustment by the user, no heat dissipation for internal electronic components, and the requirement for an external power supply.

### (2) Technical Solutions

In order to achieve the above-mentioned objective, the present invention provides the following technical solutions.

The present invention provides a temperature controller for a gas oven, including a control module, a temperature measurement module, a prompt module, and a gas regulating module.

The control module is connected to the temperature measurement module, the prompt module, and the gas regulating module, respectively, to transmit a signal, and realizes automatic temperature control adjustment through stepwise adjustment and stepless linear adjustment. The temperature measurement module is arranged in the oven to measure a temperature in the oven and return the temperature to the control module.

The prompt module is configured to receive an excessive temperature or a normal temperature of the control module, and provide a prompt.

The gas regulating module is configured to receive a temperature and a control quantity returned by the control module, and control an air intake quantity, to adjust the temperature or turn on or turn off the oven.

The temperature controller further includes a micro-switch. An on signal and an off signal of the micro-switch, namely a high-level binary level signal and a low-level binary level signal, are transmitted to the control module. The control module determines whether each micro-switch is in an on state, that is, an operating state of each ignition and flame-off button.

Specifically, the temperature measurement module is a temperature sensor arranged in the oven to measure an internal temperature. An input circuit of the temperature sensor controls a solenoid valve drive circuit and a solenoid valve for temperature control.

Specifically, the temperature controller further includes a communication module configured to communicate with a mobile phone application (APP) or a remote control terminal for remote control, and a mobile phone communicates with the communication module through a network signal to transmit an instruction signal to the communication module.

Specifically, the temperature controller further includes an ignition and flame-off button, and the ignition and flame-off button for the gas oven is installed on a front panel.

Specifically, a gas supply pipeline includes a manually operated temperature regulating valve, and a proportional valve is controlled by manually operating the temperature regulating valve to control the air intake quantity.

Specifically, the temperature controller further includes a first indicator light and a second indicator light configured to indicate whether the temperature exceeds a preset temperature or the oven is shut down.

Specifically, an ignition operation is performed by operating the ignition and flame-off button for the gas oven, and temperature data supplied by the temperature sensor through a sensor signal input circuit is monitored. When the measured temperature reaches or exceeds the preset temperature for the gas oven, the controller drives the circuit proportional valve through the solenoid valve to adjust the air intake quantity of the proportional valve.

Specifically, the temperature controller further includes a prompt buzzer, and the prompt buzzer is energized through a buzzer drive circuit, so that the prompt buzzer continuously buzzes for a preset time.

The present invention provides a gas oven, including an oven body. A gas nozzle is fixedly installed on the inner wall of the oven body. A hob is fixedly installed at the top of the oven body. A temperature sensor is fixedly installed on the inner wall of the hob. The temperature regulating valve, the proportional valve and the solenoid valve are fixedly installed on the inner bottom wall of a casing.

Preferably, a main support leg and an auxiliary support leg are fixedly installed at the bottom of the oven body separately. A heat insulation plate is fixedly installed on the inner side wall of the oven body, and the heat insulation plate divides the inside of the oven body into a heat insulation chamber and a heating chamber. The casing is fixedly installed on a side of the oven body. An open plate and a connecting plate are fixedly installed at the bottom of the oven body. A partition plate is fixedly installed on the inner wall of the casing, and a casing door is rotatably connected to the surface of the casing through a hinge. A battery pack is slidably connected to the top of the partition plate. A fan, the communication module and an ARM (or 8051) chip-based controller are fixedly installed on the top of the partition plate. A side of the casing is provided with a heat dissipation port. An air inlet is formed on the back side of the casing. An electric telescopic rod is fixedly installed on a side of the connecting plate. An adapter plate is fixedly connected to an end of the electric telescopic rod, and a closing plate is fixedly connected to the top of the adapter plate. The electric telescopic rod is fixedly connected to the inner wall of the casing. An output end of the ARM (or 8051) chip-based controller is electrically connected to an input end of the electric telescopic rod, an input end of the temperature regulating valve, an input end of the proportional valve and an input end of the solenoid valve, respectively. The ARM (or 8051) chip-based controller is electrically connected to the communication module bidirectionally, and an output end of the temperature sensor is electrically connected to an input end of the ARM (or 8051) chip-based controller.

Further, a handle is fixedly installed on the other side of the oven body, and a moving wheel is rotatably connected to the bottom of the auxiliary support leg through a bearing. A storage board is fixedly installed on the surface of the main support leg, and a side of the storage board is fixedly installed on the surface of the auxiliary support leg. A side of the hob is provided with a cleaning port. A trash box is fixedly installed on the surface of the oven body, and the cleaning port is located directly above the trash box. The partition plate divides the inside of the casing into a duct chamber, a power chamber and a control chamber. The surface of the battery pack is provided with a hidden groove, and a handle is rotatably connected to the inner side wall of the hidden groove through a bearing. The heat dissipation plate is fixedly installed on the top of the ARM (or 8051) chip-based controller. A heat dissipation fin is fixedly connected to the top of the heat dissipation plate. Each of the inner wall of the air inlet and the inner wall of the heat dissipation port is provided with a dust cover.

Further, a load circuit is connected to the control module, and a silicon-controlled rectifier is installed on the load circuit. The gas regulating module is electrically connected to the load circuit. The silicon-controlled rectifier and the solenoid valve drive circuit are connected in series in the load circuit.

### (3) Advantages

Compared with the prior art, the present invention provides a temperature-controlled gas oven, which has the following advantages.

1. In the temperature-controlled gas oven, through the cooperation of the communication module and the ARM (or 8051) chip-based controller, the user can use a mobile phone to communicate with the communication module through a network signal, and then transmit an instruction signal to the communication module through the mobile phone. Subsequently, the communication module transmits the instruction signal to the ARM (or 8051) chip-based controller, and the ARM (or 8051) chip-based controller transmits electrical signals to the temperature regulating valve, the proportional valve, and the solenoid valve according to the preset instruction, thereby automatically adjusting the gas stove, which is convenient to operate.

2. In the temperature-controlled gas oven, the air in the control chamber is continuously blown out through the heat dissipation port through the cooperation of the fan. The control chamber draws in the outside air from the air inlet under the action of negative pressure, thereby forming a circulating air passage, so as to rapidly dissipate heat inside the control chamber to avoid overheating and damaging the electronic components inside the gas oven, which is conducive to use.

3. In the temperature-controlled gas oven, through the cooperation of the battery pack, the gas oven has an independent power supply, thereby avoiding the restriction of the external power supply on the movement of the equipment. Through the cooperation of the partition plate, the user can quickly replace the battery pack, thereby further improving the endurance of the battery pack, which is conducive to use.

### BRIEF DESCRIPTION OF THE DRAWINGS

FIG. 1 is a structural diagram of the system of the present invention;

FIG. 2 is a structural diagram of the present invention;

FIG. 3 a side perspective view of the present invention;

FIG. 4 is a bottom perspective view of the present invention; and

FIG. 5 is a structural diagram of the internal structure of the casing of the present invention.

In the figures: 1—oven body; 2—heat insulation plate; 3—heat insulation chamber; 4—heating chamber; 5—gas nozzle; 6—handle; 7—main support leg; 8—auxiliary support leg; 9—moving wheel; 10—storage board; 11—temperature sensor; 12—cleaning port; 13—trash box; 14—hob; 15—casing; 16—open plate; 17—connecting plate; 18—adapter plate; 19—electric telescopic rod; 20—closing plate; 21—battery pack; 22—hidden groove; 23—handle; 24—fan; 25—heat dissipation plate; 26—heat dissipation fin; 27—air inlet; 28—ARM (or 8051) chip—based controller; 29—heat dissipation port; 30—communication module; 31—duct chamber; 32—power chamber; 33—control chamber; 34—temperature regulating valve, 35—proportional valve, 36—solenoid valve; 37—casing door; 38—partition plate; 39—pipeline; 40—ignition and flame—off button; 41—first indicator light; 42—second indicator light; 43—prompt buzzer; 44—switch; 45—proportional valve; 46—ignition electrode.

### DETAILED DESCRIPTION OF THE EMBODIMENTS

The technical solutions in the embodiments of the present invention will be clearly and completely described below with reference to the drawings in the embodiments of the present invention. Obviously, the described embodiments are only a part of the embodiments of the present invention, rather than all the embodiments. Based on the embodiments of the present invention, all other embodiments obtained by those skilled in the art without creative efforts shall fall within the scope of protection of the present invention.

### Embodiments

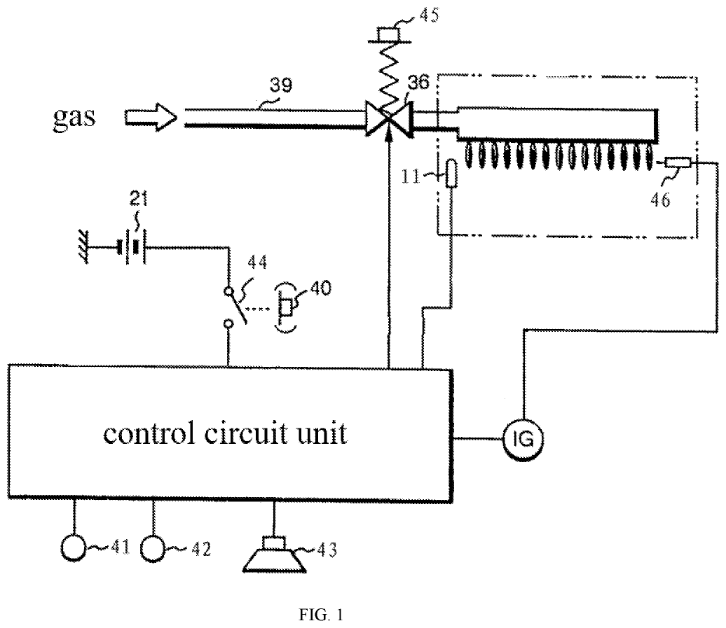

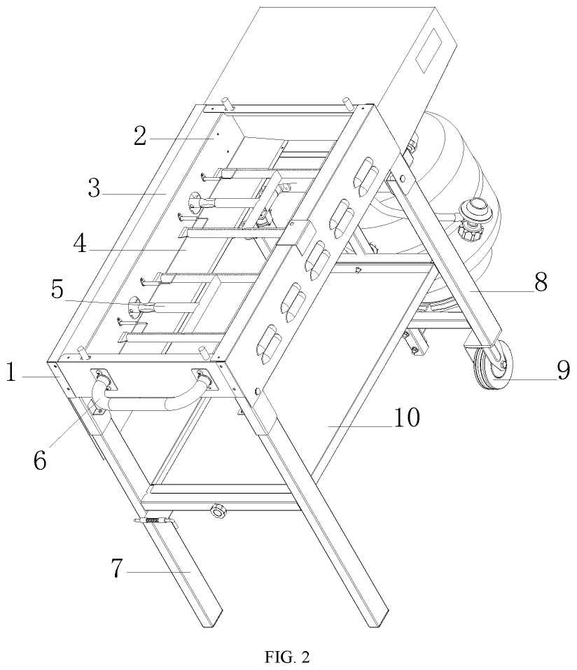

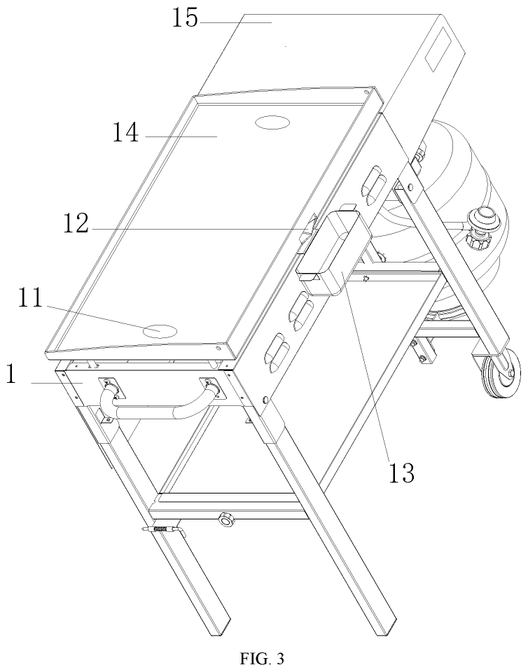

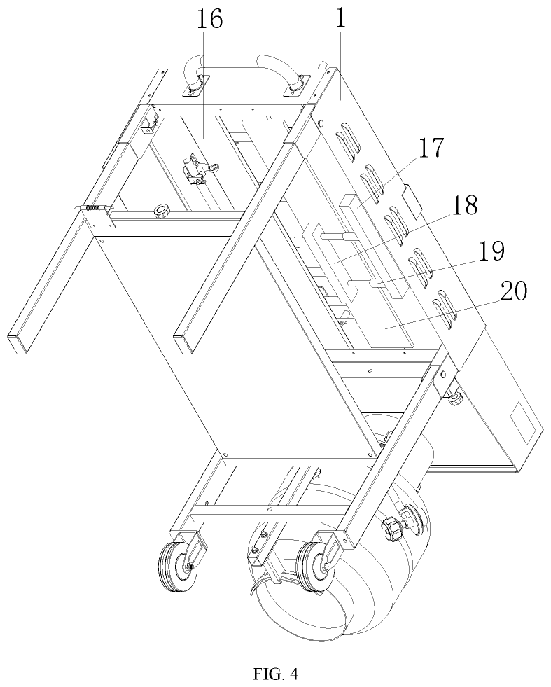

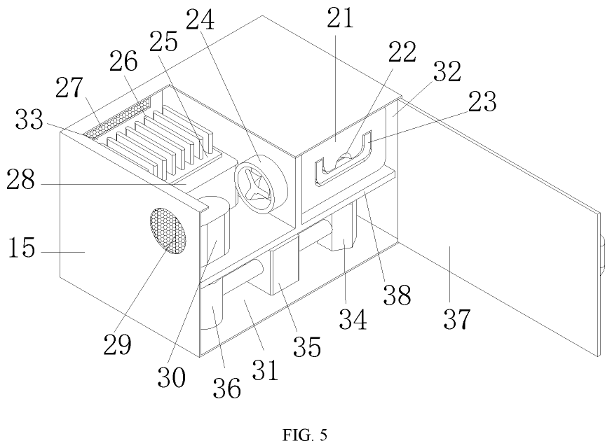

Referring to FIGS. 1-5, a temperature-controlled gas oven includes the casing 15, and the temperature regulating valve 34, the proportional valve 35 and the solenoid valve 36 are fixedly installed on the inner bottom wall of the casing 15 separately.

In the present embodiment, the model of the ARM (or 8051) chip-based controller 28 is FX1S-30MT-001, the model of the temperature sensor 11 is WZPB-230, the model of the solenoid valve 36 is 2-way normally closed, the model of the proportional valve 35 is ITV2050-312L, and the model of the temperature regulating valve 34 is ZDLP. Through the cooperation of the hob and the temperature sensor 11, the temperature of the hob can be accurately monitored in real time. Through the cooperation of the communication module 30 and the ARM (or 8051) chip-based controller 28, the user can use a mobile phone to communicate with the communication module 30 through a network signal, and then transmit an instruction signal to the communication module 30 through the mobile phone. Subsequently, the communication module 30 transmits the instruction signal to the ARM (or 8051) chip-based controller 28, and the ARM (or 8051) chip-based controller 28 transmits electrical signals to the temperature regulating valve 34, the proportional valve 35, and the solenoid valve 36 according to the preset instruction, thereby automatically adjusting the gas stove.

The ignition and flame-off button 40 for the gas oven is installed on the front panel. The gas is supplied to the gas oven through the gas supply pipeline 39 that includes the solenoid valve 36. In addition, the gas supply pipeline 39 further includes the temperature regulating valve 34 that can be manually operated by the user. During combustion operation, the temperature controller further includes the temperature sensor 11, the first indicator light 41, the second indicator light 42 and the prompt buzzer 43, as well as a control circuit unit that uses a power supply as an operating power source to control the actions of the solenoid valve 36, the first indicator light 41, the second indicator light 42, and the prompt buzzer 43, etc. The ignition electrode 46 is an igniter that generates spark discharge. The temperature sensor 11 feeds data back to the control module, and the control module controls the solenoid valve drive circuit and the solenoid valve 36 for temperature control.

In the present embodiment, a method for the automatic temperature control adjustment includes: the temperature sensor 11 first detects a corresponding temperature signal and feeds the temperature signal back to the control module. The control module controls the on-off and magnitude of the current of the silicon-controlled rectifier for stepwise adjustment to control the solenoid valve drive circuit, so as to meet the temperature requirements for the oven.

The temperature controller further includes a micro-switch. Signals corresponding to the on-off of the micro-switch, namely a high-level binary level signal and a low-level binary level signal, are transmitted to the control module. The control module determines whether each micro-switch is in an on state, that is, an operating state of each ignition and flame-off button.

The user performs an ignition operation by operating the ignition and flame-off button 40 for the gas oven, and monitors the temperature data supplied by the temperature sensor 11 through the sensor signal input circuit. In addition, when the measured temperature reaches or exceeds the preset temperature (for example, 260° C.) for the gas oven, the controller drives the circuit proportional valve through the solenoid valve to adjust the air intake quantity of the proportional valve. Through a light drive circuit, the indicator lights 41 and 42 are intermittently energized. The prompt buzzer 43 is energized through a buzzer drive circuit, so that the prompt buzzer 43 continuously buzzes for a preset time.

The gas nozzle 5 is fixedly installed on the inner side wall of the oven body 1. The main support leg 7 and the auxiliary support leg 8 are fixedly installed at the bottom of the oven body 1 separately. The hob 14 is fixedly installed at the top of the oven body 1. The temperature sensor 11 is fixedly installed on the inner wall of the hob 14. The casing 15 is fixedly installed on a side of the oven body 1. The open plate 16 and the connecting plate 17 are fixedly installed at the bottom of the oven body 1 separately. The electric telescopic rod 19 is fixedly installed on a side of the connecting plate 17. The adapter plate 18 is fixedly connected to an end of the electric telescopic rod 19. The closing plate 20 is fixedly connected to the top of the adapter plate 18. The electric telescopic rod 19 is fixedly connected to the inner wall of the casing 15. The partition plate 38 is fixedly installed on the inner wall of the casing 15. The casing door 37 is rotatably connected to the surface of the casing 15 through a hinge. The battery pack 21 is slidably connected to the top of the partition plate 38. The fan 24, the communication module 30 and the ARM (or 8051) chip-based controller 28 are fixedly installed on the top of the partition plate 38 separately. A side of the casing 15 is provided with the heat dissipation port 29. The air inlet 27 is formed on the back side of the casing 15. The adapter plate 18 is pushed by the electric telescopic rod 19 to drive the closing plate 20 to approach the opening plate 16, so that the air quantity inside the oven body 1 is reduced. Meanwhile, the gas quantity inside the oven body 1 is reduced through the cooperation of the temperature regulating valve 34, thereby realizing the precise control of the temperature of the hob 14. Through the cooperation of the fan 24, the air inside the control chamber 33 is continuously blown out through the heat dissipation port 29, and the control chamber 33 draws in the outside air from the air inlet 27 under the action of negative pressure, thereby forming a circulating air passage, so as to rapidly dissipate heat inside the control chamber 33 to avoid overheating and damaging the electronic components inside the gas oven. The battery pack 21 serves as an independent power supply, thereby avoiding the restriction of the external power supply on the movement of the equipment. Through the cooperation of the partition plate 38, the user can quickly replace the battery pack 21, which further improves the endurance of the battery pack 21, and is conducive to use.

When the equipment is running, the user establishes a network connection between a mobile phone and the communication module 30, and then selects the preferred recipe through the mobile phone. The communication module 30 receives an instruction signal transmitted from the mobile phone and transmits the instruction signal to the ARM (or 8051) chip-based controller 28. The ARM (or 8051) chip-based controller 28 transmits electrical signals to the electric telescopic rod 19, the temperature regulating valve 34, the proportional valve 35 and the solenoid valve 36, respectively, according to the preset instruction. The temperature regulating valve 34, the proportional valve 35 and the solenoid valve 36 adjust the gas intake quantity in response to the electrical signals. When the hob 14 is heated, the temperature sensor 11 monitors the temperature of the hob 14 and converts real-time temperature data into electrical signals and transmits the electrical signals to the ARM (or 8051) chip-based controller 28. The ARM (or 8051) chip-based controller 28 compares the real-time temperature data with the preset temperature data, and adjusts the gas intake quantity and air intake quantity in real time according to the comparison results. When the equipment is running, the fan 24 is activated to continuously blow out the air inside the control chamber 33 through the heat dissipation port 29. A negative pressure is formed inside the control chamber 33, and the outside air is drawn into the control chamber 33 under the action of atmospheric pressure, thereby forming a circulating air passage inside the control chamber 33, so as to dissipate heat inside the control chamber 33. The equipment is powered by the battery pack 21, which avoids the restriction of the external power supply on the movement of the equipment, facilitates moving the equipment by the user, and improves the flexibility of using the equipment.

The heat insulation plate 2 is fixedly installed on the inner side wall of the oven body 1. The heat insulation plate 2 divides the inside of the oven body 1 into the heat insulation chamber 3 and the heating chamber 4. In the present embodiment, through the cooperation of the heat insulation chamber 3 and the heating chamber 4, the surface of the oven body 1 can be prevented from overheating, thereby preventing the user from being scalded by the surface of the oven body 1 during use. The handle 6 is fixedly installed on the other side of the oven body 1, and the moving wheel 9 is rotatably connected to the bottom of the auxiliary support leg 8 through a bearing. In the present embodiment, it is convenient for the user to move the equipment through the cooperation of the handle 6 and the moving wheel 9, which is conducive to use. Specifically, the storage board 10 is fixedly installed on the surface of the main support leg 7, and one side of the storage board 10 is fixedly installed on the surface of the auxiliary support leg 8. In the present embodiment, through the cooperation of the storage board 10, the user can place objects on the storage board 10, which is convenient to use. The cleaning port 12 is formed on one side of the hob 14. The trash box 13 is fixedly installed on the surface of the oven body 1, and the cleaning port 12 is located directly above the trash box 13. In the present embodiment, through the cooperation of the cleaning port 12 and the trash box 13, the user can remove residues from the top of the hob 14 through the cleaning port 12, such that the residues fall into the trash box 13 to facilitate subsequent treatment by the user. The partition plate 38 divides the inside of the casing 15 into the duct chamber 31, the power chamber 32 and the control chamber 33. The gas pipeline, the battery pack 21 and the electronic components can be classified for centralized management through the cooperation of the duct chamber 31, the power chamber 32 and the control chamber 33 to facilitate subsequent maintenance of the equipment. The surface of the battery pack 21 is provided with the hidden groove 22, and the handle 23 is rotatably connected to the inner side wall of the hidden groove 22 through a bearing.

In the present embodiment, through the cooperation of the hidden groove 22 and the handle 23, it is convenient for the user to hold the handle 23 to replace the battery pack 21, which is conducive to use.

The heat dissipation plate 25 is fixedly installed on the top of the ARM (or 8051) chip-based controller 28. The heat dissipation fin 26 is fixedly connected to the top of the heat dissipation plate 25. Each of the inner wall of the air inlet 27 and the inner wall of the heat dissipation port 29 is provided with a dust cover.

In the present embodiment, through the cooperation of the heat dissipation plate 25 and the heat dissipation fin 26, the heat dissipation efficiency of the ARM (or 8051) chip-based controller 28 can be further improved. Through the cooperation of the dust cover, impurities can be prevented from entering the control chamber 33, which is conducive to use. The output end of the ARM (or 8051) chip-based controller 28 is electrically connected to the input end of the electric telescopic rod 19, the input end of the temperature regulating valve 34, the input end of the proportional valve 35 and the input end of the solenoid valve 36. The ARM (or 8051) chip-based controller 28 is electrically connected to the communication module 30 bidirectionally, and the output end of the temperature sensor 11 is electrically connected to the input end of the ARM (or 8051) chip-based controller 28.

In the present embodiment, through the cooperation of the ARM (or 8051) chip-based controller 28 and the communication module 30, users can use a mobile phone to communicate with the communication module 30 to facilitate performing remote operations. The electric telescopic rod 19 moves in response to the electrical signals and pushes the adapter plate 18 to move, the adapter plate 18 pushes the closing plate 20 to move, and the closing plate 20 moves closer to or away from the open plate 16, so that the air intake quantity inside the oven 1 is changed and the flames at the gas nozzle 5 are controlled. The temperature-controlled gas oven can accurately monitor the temperature of the hob in real time through the cooperation of the hob and the temperature sensor. The adapter plate is pushed by the electric telescopic rod to drive the closing plate to approach the open plate so that the air quantity inside the oven body is reduced. Meanwhile, the gas quantity inside the oven body is reduced through the cooperation of the temperature regulating valve, thereby realizing the precise control of the temperature of the hob, which is conducive to use.

Finally, it should be noted that, the above descriptions are only preferred embodiments of the present invention and are not intended to limit the present invention. Although the present invention has been described in detail with reference to the foregoing embodiments, those skilled in the art can still modify the technical solutions described in the foregoing embodiments, or equivalently replace some of the technical features. Any modification, equivalent replacement, improvement, and the like made within the spirit and principle of the present invention shall fall within the scope of protection of the present invention.

What is claimed is:

1. A temperature controller for a gas oven, comprising
a control module, a temperature measurement module, a prompt module, and a gas regulating module;
wherein
the control module is connected to the temperature measurement module, the prompt module, and the gas regulating module, respectively, to transmit a signal, and performs automatic temperature control adjustment through a stepwise adjustment and a stepless linear adjustment;
the temperature measurement module is arranged in the gas oven to measure a temperature in the gas oven and return the temperature to the control module;
the prompt module is configured to receive an excessive temperature signal or a normal temperature signal of the control module, and provide a prompt of excessive temperature;
the gas regulating module is configured to receive a temperature signal and a control quantity signal returned by the control module, and control an air intake quantity, to adjust the temperature or turn on or turn off the gas oven;
the temperature controller further comprises a micro-switch;
an on signal and an off signal of the micro-switch are transmitted to the control module, wherein the on signal and the off signal of the micro-switch are a high-level binary level signal and a low-level binary level signal, respectively; and
the control module determines whether the micro-switch is in an on state, wherein the on state indicates an operating state of an ignition and flame-off button.

2. The temperature controller according to claim 1, wherein
the temperature measurement module is a temperature sensor arranged in the gas oven to measure an internal temperature; and
an input circuit of the temperature sensor controls a solenoid valve drive circuit and a solenoid valve to control the temperature.

3. The temperature controller according to claim 1, further comprising a communication module configured to communicate with a mobile phone APP or a remote control terminal for remote control, and
a mobile phone communicates with the communication module through a network signal to transmit an instruction signal to the communication module.

4. The temperature controller according to claim 1, further comprising the ignition and flame-off button, and the ignition and flame-off button for the gas oven is installed on a front panel.

5. The temperature controller according to claim 2, wherein
a gas supply pipeline comprises a temperature regulating valve, and a proportional valve is controlled by manually operating the temperature regulating valve to control the air intake quantity.

6. The temperature controller according to claim 5, further comprising a first indicator light and a second indicator light, wherein the first indicator light and the second indicator light are configured to indicate whether the temperature exceeds a preset temperature or the gas oven is shut down.

7. The temperature controller according to claim 6, wherein
an ignition operation is performed by operating the ignition and flame-off button for the gas oven, and temperature data supplied by the temperature sensor through a sensor signal input circuit is monitored;
when a measured temperature reaches or exceeds the preset temperature for the gas oven, the control module drives the proportional valve through the solenoid valve drive circuit to adjust the air intake quantity of the proportional valve.

8. The temperature controller according to claim 7, further comprising a prompt buzzer; the prompt buzzer is energized through a buzzer drive circuit, and the prompt buzzer continuously buzzes for a preset time.

9. A temperature-controlled gas oven using the temperature controller according to claim 1, comprising an oven body;
wherein
a gas nozzle is fixedly installed on an inner side wall of the oven body;
a hob is fixedly installed at a top of the oven body, and a temperature sensor is fixedly installed on an inner wall of the hob; and
a temperature regulating valve, a proportional valve and a solenoid valve are fixedly installed on an inner bottom wall of a casing separately.

10. The temperature-controlled gas oven according to claim 9, wherein
a main support leg and an auxiliary support leg are fixedly installed at a bottom of the oven body separately;
a heat insulation plate is fixedly installed on the inner side wall of the oven body;
the heat insulation plate divides an inside of the oven body into a heat insulation chamber and a heating chamber;
the casing is fixedly installed on a first side of the oven body;
an open plate and a connecting plate are fixedly installed at the bottom of the oven body;
a partition plate is fixedly installed on an inner wall of the casing;
a casing door is rotatably connected to a surface of the casing through a hinge;
a battery pack is slidably connected to a top of the partition plate;
a fan, a communication module and an ARM (or 8051) chip-based controller are fixedly installed on the top of the partition plate;
a side of the casing is provided with a heat dissipation port, and an air inlet is formed on a back side of the casing;
an electric telescopic rod is fixedly installed on a side of the connecting plate, and an adapter plate is fixedly connected to an end of the electric telescopic rod;
a closing plate is fixedly connected to a top of the adapter plate;
the electric telescopic rod is fixedly connected to the inner wall of the casing;
an output end of the ARM (or 8051) chip-based controller is electrically connected to an input end of the electric telescopic rod, an input end of the temperature regulating valve, an input end of the proportional valve and an input end of the solenoid valve, respectively;
the ARM (or 8051) chip-based controller is electrically connected to the communication module bidirectionally, and
an output end of the temperature sensor is electrically connected to an input end of the ARM (or 8051) chip-based controller.

11. The temperature-controlled gas oven according to claim 10, wherein
a first handle is fixedly installed on a second side of the oven body;
a moving wheel is rotatably connected to a bottom of the auxiliary support leg through a first bearing;
a storage board is fixedly installed on a surface of the main support leg;
a side of the storage board is fixedly installed on a surface of the auxiliary support leg;
a side of the hob is provided with a cleaning port;
a trash box is fixedly installed on a surface of the oven body, and the cleaning port is located directly above the trash box;
the partition plate divides an inside of the casing into a duct chamber, a power chamber and a control chamber;
a surface of the battery pack is provided with a hidden groove, a second handle is rotatably connected to an inner side wall of the hidden groove through a second bearing;
a heat dissipation plate is fixedly installed on a top of the ARM (or 8051) chip-based controller;
a heat dissipation fin is fixedly connected to a top of the heat dissipation plate; and
each of an inner wall of the air inlet and an inner wall of the heat dissipation port is provided with a dust cover.

12. The temperature-controlled gas oven according to claim 10, wherein
a load circuit is connected to the control module, and a silicon-controlled rectifier is installed on the load circuit;
the gas regulating module is electrically connected to the load circuit; and
the silicon-controlled rectifier and a solenoid valve drive circuit are connected in series in the load circuit.

13. The temperature-controlled gas oven according to claim 9, wherein
the temperature measurement module is the temperature sensor arranged in the gas oven to measure an internal temperature; and
an input circuit of the temperature sensor controls a solenoid valve drive circuit and the solenoid valve to control the temperature.

14. The temperature-controlled gas oven according to claim 9, wherein
the temperature controller further comprises a communication module configured to communicate with a mobile phone APP or a remote control terminal for remote control, and
a mobile phone communicates with the communication module through a network signal to transmit an instruction signal to the communication module.

15. The temperature-controlled gas oven according to claim 9, wherein
the temperature controller further comprises the ignition and flame-off button, and the ignition and flame-off button for the gas oven is installed on a front panel.

16. The temperature-controlled gas oven according to claim 13, wherein
a gas supply pipeline comprises the temperature regulating valve, and the proportional valve is controlled by manually operating the temperature regulating valve to control the air intake quantity.

17. The temperature-controlled gas oven according to claim 16, wherein
the temperature controller further comprises a first indicator light and a second indicator light, wherein the first indicator light and the second indicator light are configured to indicate whether the temperature exceeds a preset temperature or the gas oven is shut down.

18. The temperature-controlled gas oven according to claim 17, wherein
an ignition operation is performed by operating the ignition and flame-off button for the gas oven, and temperature data supplied by the temperature sensor through a sensor signal input circuit is monitored;
when a measured temperature reaches or exceeds the preset temperature for the gas oven, the temperature controller drives the proportional valve through the solenoid valve to adjust the air intake quantity of the proportional valve.

19. The temperature-controlled gas oven according to claim 18, wherein
the temperature controller further comprises a prompt buzzer; the prompt buzzer is energized through a buzzer drive circuit, and the prompt buzzer continuously buzzes for a preset time.

20. The temperature-controlled gas oven according to claim 13, wherein
a main support leg and an auxiliary support leg are fixedly installed at a bottom of the oven body separately;
a heat insulation plate is fixedly installed on the inner side wall of the oven body;
the heat insulation plate divides an inside of the oven body into a heat insulation chamber and a heating chamber;
the casing is fixedly installed on a first side of the oven body;
an open plate and a connecting plate are fixedly installed at the bottom of the oven body;
a partition plate is fixedly installed on an inner wall of the casing;
a casing door is rotatably connected to a surface of the casing through a hinge;
a battery pack is slidably connected to a top of the partition plate;
a fan, a communication module and an ARM (or 8051) chip-based controller are fixedly installed on the top of the partition plate;
a side of the casing is provided with a heat dissipation port, and an air inlet is formed on a back side of the casing;
an electric telescopic rod is fixedly installed on a side of the connecting plate, and an adapter plate is fixedly connected to an end of the electric telescopic rod;
a closing plate is fixedly connected to a top of the adapter plate;
the electric telescopic rod is fixedly connected to the inner wall of the casing;
an output end of the ARM (or 8051) chip-based controller is electrically connected to an input end of the electric telescopic rod, an input end of the temperature regulating valve, an input end of the proportional valve and an input end of the solenoid valve, respectively;
the ARM (or 8051) chip-based controller is electrically connected to the communication module bidirectionally, and
an output end of the temperature sensor is electrically connected to an input end of the ARM (or 8051) chip-based controller.
